(19) United States
(12) Patent Application Publication
(10) Pub. No.: US 2006/0183057 A1
(43) Pub. Date: Aug. 17, 2006

(54) Patterning method

(76) Inventors: Katsuhiko Mitani, Hikari-shi (JP); Hiroshi Fukuda, Tokyo (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/055,623

(22) Filed: Feb. 11, 2005

(51) Int. Cl. G03F 7/00

(52) U.S. Cl. 430/322

(57) ABSTRACT

Formation of a photomask in the conventional art requires significant cost and time. The invention provides a patterning method of forming a desired latent image pattern by irradiating a resist film formed on a substrate with focused light beam. The method comprising adjusting intensity of the focused light beam or size thereof on the resist film depending on a design of the pattern to irradiate the resist film, thereby achieving a desired pattern with reasonable cost and time.

### BACKGROUND OF THE INVENTION

1. Field of the Invention

The invention relates to a method of patterning a resist film formed on a substrate such as a semiconductor wafer, and to a patterning method of forming a photolithographic image by irradiating a resist film on a substrate.

2. Description of the Related Art

In a process for forming semiconductor devices from a substrate such as a semiconductor wafer, a pattern is formed on the substrate using a mask of resist film or the like. Formation of this kind of pattern, such as fabrication of a pattern for a microfluidic device, requires preparing beforehand a photomask including a desired pattern with a width ranging from several to several hundreds of micrometers. Typically, the photomask is fabricated using electron-beam direct-writing lithography and the process of etching a chromium film. Next, a contact exposure apparatus or mask aligner is used to hold the photomask in contact with, or nearly in contact with the resist film applied and formed on the substrate. A desired latent image pattern is formed by irradiating the resist film with ultraviolet light through the photomask. The resist film is then subjected to a prescribed heat treatment (bake process) followed by development process, thereby transforming the latent image pattern into a resist feature pattern. When positive resist is used, the latent image pattern formed by ultraviolet irradiation is dissolved away in the development process. Conversely, when negative resist is used, only the latent image pattern area remains after the development process to form a resist feature.

In the research and development phase of microfluidic devices and the like, it is essential to optimize dimensions and arrangements of the pattern as well as its configuration depending on different applications by fine tuning them through trial and error, which involves frequent modifications of the device pattern. The pattern modification requires returning to preparing another photomask, which has to rely on any specialized photomask manufacturer that owns expensive electron-beam direct-writing lithography equipment. This causes a problem that the pace of research and development is limited by the delivery time of photomasks, and that the cost for photomasks increases.

Furthermore, in a typical photomask, the presence and absence of light shielding material (chromium film) is used to form a latent image pattern in the resist film. As a result, the resist pattern obtained after the development process, especially the profile along the resist film thickness, has a sharp feature essentially based on the binary information of the presence and absence of irradiation. On the other hand, in the field of microfluidic devices and the like, a channel pattern feature of a profile that smoothly varies along the resist film thickness is desired for preventing occurrence of turbulence in fluid. A resist pattern having such a profile may be formed by an exposure method that uses a gray-scale mask, which has a stepwise variation of the density of dot patterns to gradually change transmittance on a per-zone basis. However, it is cumbersome to design and manufacture the gray-scale mask, which significantly increases the cost and time for fabricating photomasks. It is thus impractical to apply this method in the phase of research or trial production for microfluidic devices and the like that needs trial and error.

### SUMMARY OF THE INVENTION

An object of the invention is to provide a patterning method that can achieve a desired pattern with reasonable cost and time.

Another object of the invention is to provide a patterning method that can achieve a desired pattern conveniently with high precision.

Yet another object of the invention is to provide a patterning method that can achieve modification of a target pattern easily in a short period of time.

The above objects are achieved by a patterning method of forming a desired latent image pattern by irradiating a resist film formed on a substrate with focused light beam, the method comprising adjusting intensity of the focused light beam or size thereof on the resist film depending on a design of the pattern to irradiate the resist film.

The method may further comprise varying the diameter of the focused light beam on the resist film in a range of 5 μm to 500 μm. Preferably, optical system including some lenses and a aperture may be placed between a source of the focused light beam and the resist film, and the diameter of the focused light beam may be adjusted by adjusting the aperture size.

The amount of irradiation exposure density on the resist film may be adjusted while the diameter of the focused light beam is adjusted. The amount of irradiation exposure density on the resist film can be adjusted by controlling intensity of the focused light beam using an optical intensity modulation element provided in optical system placed between a source of the focused light beam and the resist film. The amount of irradiation exposure density on the resist film may be adjusted by controlling a relative writing speed of the focused light beam on the resist surface.

The above objects are achieved by a patterning method of forming a desired latent image pattern by irradiating a resist film formed on a substrate with single focused light beam, the method comprising variably adjusting the irradiation direction of the focused light beam or the position of the substrate depending on a design of the pattern while irradiating the resist film with the focused light beam, which is called vector scan.

The method may further comprise adjusting sharpness of the focused light beam along the pattern. Preferably, optical system including one or more lenses and a aperture may be placed between a source of the focused light beam and the resist film, and the sharpness or depth of focus of the focused light beam may be adjusted by adjusting the numerical aperture (NA) of an objective lens using the aperture. Preferably, a semiconductor light emitting device may be used for a ultraviolet light source. The semiconductor light emitting device has an intensity distribution of emitted light primarily composed of wavelengths in the vicinity of 365 nm.

### BRIEF DESCRIPTION OF THE DRAWINGS

FIG. 1 is a schematic view showing the general configuration of an apparatus implementing a first embodiment of the patterning method of the invention.

FIG. 2 is a vertical cross-sectional view showing an example pattern formed by the first embodiment shown in FIG. 1.

FIG. 3 is a schematic view showing the general configuration of an apparatus implementing a second embodiment of the patterning method of the invention.

FIG. 4 is a vertical cross-sectional view showing an example pattern formed by the second embodiment shown in FIG. 3.

### DETAILED DESCRIPTION OF THE PREFERRED EMBODIMENTS

Embodiments of the invention are described in detail with reference to the drawings.

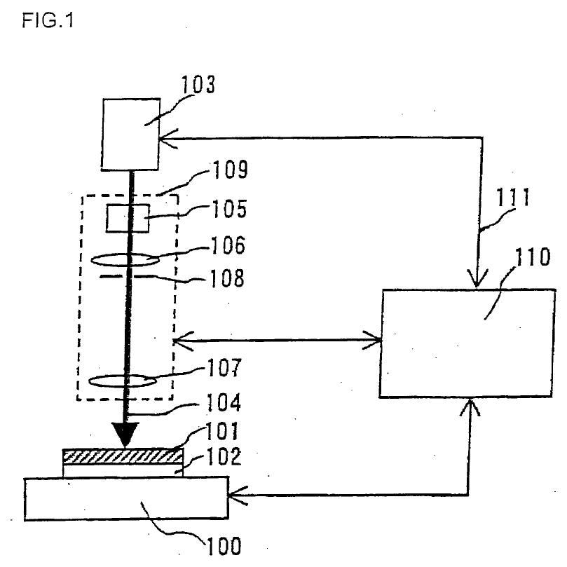

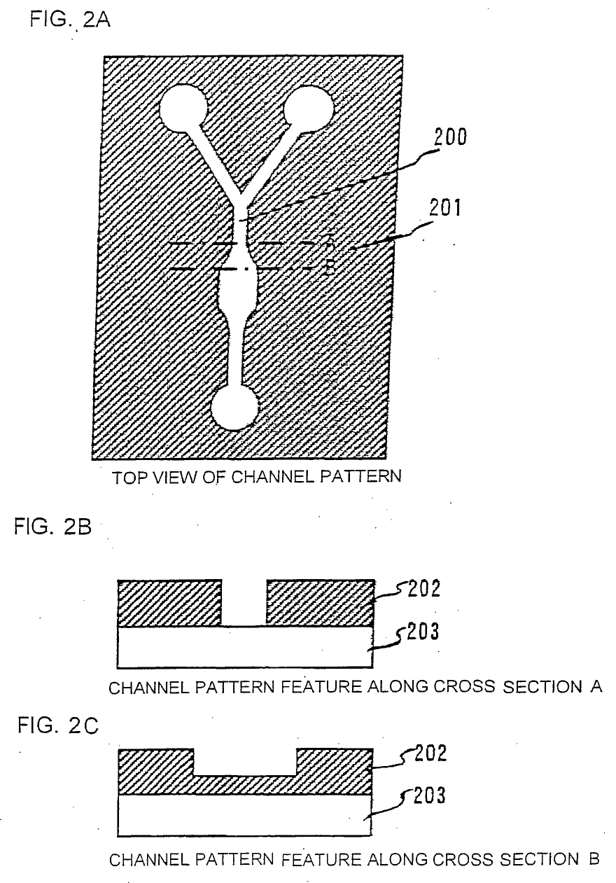

FIG. 1 shows a first embodiment of a patterning apparatus that implements the patterning method of the invention. That is, FIG. 1 is a schematic view showing the general configuration of an apparatus according to this embodiment. FIG. 2 is a vertical cross-sectional view showing an example pattern formed by using the embodiment shown in FIG. 1.

In the embodiment shown in FIG. 1, a substrate 102 with a resist film 101 applied and formed thereon is mounted on a stage 100 and the position of the substrate 102 is fixed. Next, the resist film 101 is directly exposed to focused light beam 104 from an ultraviolet light source 103 having a peak of intensity around 365 nm of wavelength. A latent image of a desired pattern is thus formed on the substrate 102. The focused light beam 104 is passed through an optical control system 109 and directed onto the resist film 101. The optical control system 109 includes at least an optical intensity modulation element 105, one or more first lenses 106, one or more second lenses 107, and a variable aperture 108.

Based on communication of a control and monitor signals 111 between a controlling computer 110 and the ultraviolet light source 103, command signals for operating the ultraviolet light source 103 and the optical control system 109 are transmitted thereto from the controlling computer 110 to precisely adjust and control the optical intensity of the focused light beam 104 at the resist film 101 and the diameter of light beam at the irradiated location.

In this embodiment, the controlling computer 110 controls the position and moving speed of the stage 100 to project the latent image of a channel pattern 200 in a microfluidic device as illustrated in FIG. 2A with adjusting the focused light beam 104 in response to its optical intensity and the location of the pattern on the substrate surface irradiated with the diameter. In this way, the latent image is formed in the vector mode in which the direction, position, and intensity of the focused light beam for irradiation are varied.

The channel pattern 200 in FIG. 2A has various portions having different widths, where a desired pattern of latent image is formed by controlling the variable aperture 108 and the like to adjust the diameter of the focused light beam 104 within the range of, typically, 5 μm to 500 μm. In addition, the optical energy density on the resist surface can be controlled by controlling the moving speed of the stage 100 in view of the diameter of the focused light beam 104.

After the latent image is formed as described above, the resist film 101 is subjected to prescribed PEB (Post Exposure Bake) and development processes to form a desired pattern of resist film. In the embodiment described herein, a positive resist film 201 is used, in which the latent image portion formed by irradiation of focused light beam 104 is dissolved away in the development process.

In the above embodiment, in order to form a desired pattern of latent image for microfluidic devices and the like in the resist film formed on the substrate, the resist film is directly exposed to the desired pattern using focused light beam in the ultraviolet region. This configuration can eliminate photomasks otherwise required in the conventional art. According to this embodiment, the channel pattern 200 shown in FIG. 2 can be formed without any photomask.

In addition, the pattern width can be varied conveniently and more smoothly than before as seen in the channel pattern 200 between A and B in FIG. 2A. That is, the diameter of the focused light beam can be controlled in response to the channel width of the major linear or curved pattern in a microfluidic device or the like. This also enables to conveniently form a latent image of a desired pattern using the vector mode equivalent to single-path writing without multiple scanning of the linear or curved pattern.

Furthermore, when the resist film is exposed to a linear or curved pattern in a mode equivalent to single-path writing, a pattern having a smoothly varied channel width can be easily formed by gradually varying the diameter of focused light beam on the resist surface. More specifically, a pattern having a smooth profile (variation of channel depth) along the resist film thickness can be formed by gradually varying the amount of irradiation per unit area on the resist film along a line or curve. For example, a pattern having a smoothly varied profile (sidewall feature of the channel) along the cross section of the resist film in a linear or curved pattern can also be formed by gradually varying the numerical aperture (NA) of the objective lens in the optical system of focused light beam along a line or curve.

In addition, the optical energy density per unit area of irradiation on the resist surface between A and B can be gradually varied. As shown in FIGS. 2B and 2C, the channel depth can be varied between the configuration like cross section A where the resist film 202 is completely dissolved to expose the surface of the substrate 203 (FIG. 2B) and the configuration where part of the resist film 202 remains on the substrate 203 (FIG. 2C). In the present embodiment, the channel is deep at cross section A and shallow at cross section B. Alternatively, the channel may be deeper at cross section B. The depth can be controlled independent of the channel width.

The ultraviolet light source used in the present embodiment is a compound semiconductor (GaN-based) LED (Light Emitting Diode) having a peak wavelength around 365 nm. It is not only less expensive than light sources such as ultraviolet lamps and gas lasers, but also easy to maintain. While a GaN-based semiconductor laser having a peak wavelength around 365 nm may be used in place of LED, a long-life laser is difficult to obtain at this time.

The optical control system 109 in the present embodiment, as a typical example, only includes an optical intensity modulation element 105, one or more first lenses 106, one or more second lenses 107, and a variable aperture 108. However, the invention is not limited thereto with respect to the configuration and positional relationship. Laser light beam having a wavelength to which the resist film 101 is not photosensitive may be passed through at least a portion of the optical control system 109 and directed onto the resist film 101 or the substrate 102 in order to monitor and control the focus condition or relative distance of the second lens 107 served as an objective lens with respect to the resist film 101 or the substrate 102. It is understood that this optical control system is effective for stable formation of latent image.

The present embodiment describes a channel pattern 200 based on positive resist film 201. However, the fabrication process for microfluidic devices includes many variations such as transferring a channel pattern to the underlying substrate using a resist film pattern as a mask, and replicating the resist film pattern by using it as a template. It is understood that positive or negative resist may be used depending on the applied process.

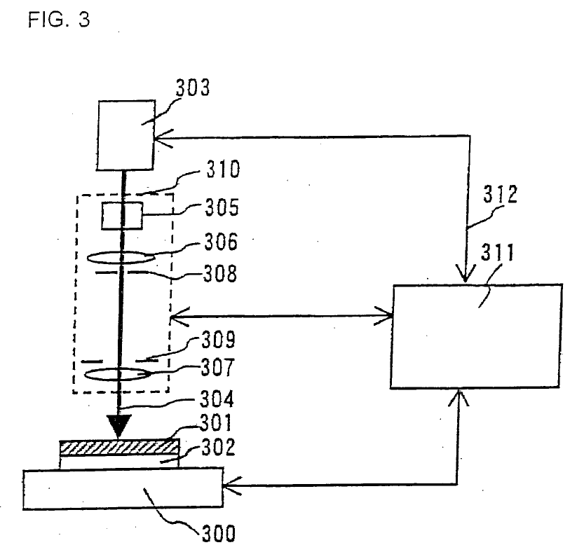

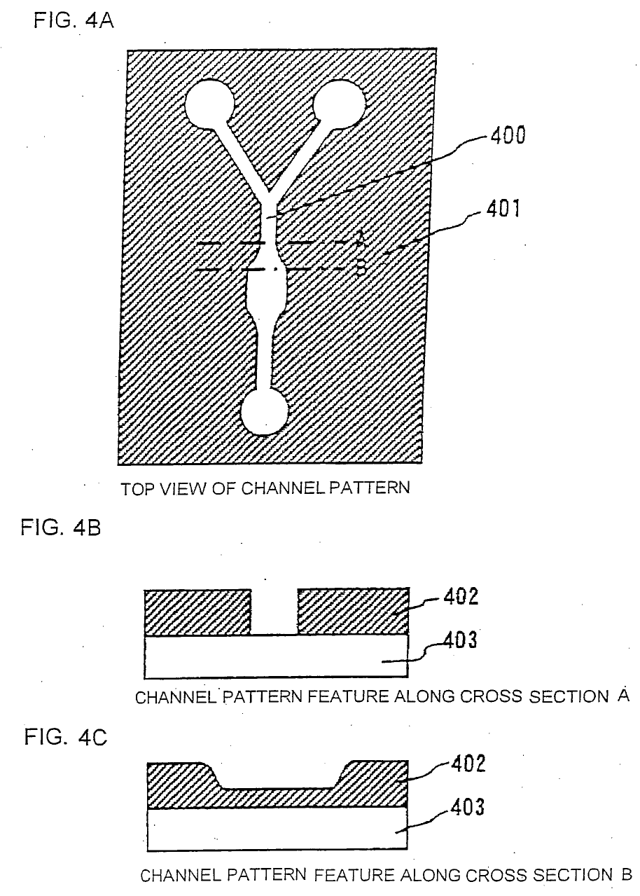

Next, a second embodiment of the invention will be described with reference to FIGS. 3 and 4. FIG. 3 is a schematic view showing the general configuration of an apparatus implementing the patterning method of the second embodiment of the invention. FIG. 4 is a vertical cross-sectional view showing an example pattern formed by using the patterning apparatus shown in FIG. 3.

In FIG. 3, a substrate 302 with a resist film 301 applied and formed thereon is mounted on a stage 300 and the position of the substrate 302 is fixed. Next, the resist film 301 is irradiated with focused light beam 304 from an ultraviolet light source 303 having a peak at a wavelength around 365 nm to directly expose the surface of the substrate 302, where a latent image of a desired pattern is formed. The focused light beam 304 is passed through an optical control system 310 and directed onto the resist film 301. The optical control system 310 is an optical system including at least an optical intensity modulation element 305, one or more first lenses 306, one or more second lenses 307, a first variable aperture 308, and a second variable aperture 309.

Based on communication of a control and monitor signal 312 between a controlling computer 311 and the ultraviolet light source 303, command signals for operating the ultraviolet light source 303 and the optical control system 310 are transmitted thereto from the controlling computer 311 to precisely adjust and control the optical intensity and the diameter of the focused light beam 304 at the resist film 301.

In this embodiment, the controlling computer 311 controls the position and moving speed of the stage 300 to conveniently form a latent image pattern of a microfluidic device as illustrated in FIG. 4A in the vector mode. In various portions having different pattern widths in FIG. 4A, a desired pattern of latent image is formed by controlling the first variable aperture 308 and the like to adjust the diameter of the focused light beam 304 within the range of, typically, 5 μm to 500 μm.

In addition, the optical energy density on the resist surface can be controlled by controlling the moving speed of the stage 300 in view of the diameter of the focused light beam 304. Moreover, independently, the second variable aperture 309 can be controlled so that the numerical aperture (NA) of the second lens 307 served as an objective lens can be adjusted to control the optical intensity profile and the sharpness of the focused light beam 304. After the latent image is formed as described above, the resist film 301 is subjected to prescribed PEB (Post Exposure Bake) and development processes to form a desired pattern of resist film.

According to the above embodiment, the channel pattern shown in FIG. 4 can be formed without any photomask. In addition, the pattern width can be varied conveniently and smoothly as seen in the channel pattern between A and B in FIG. 4A. In addition, the optical energy density per unit area of irradiation on the resist surface between A and B can be gradually varied. As shown in FIGS. 4B and 4C, the channel depth can be varied between the configuration like cross section A where the resist film 402 is completely dissolved to expose the surface of the substrate 403 (FIG. 4B) and the configuration where part of the resist film 402 remains on the substrate 403 (FIG. 4C). Moreover, in the present embodiment, as described above, the second variable aperture 309 can be controlled so that the numerical aperture (NA) of the second lens 307 served as an objective lens can be increased at cross section A and decreased at cross section B. As shown in FIGS. 4B and 4C, this can achieve a vertical feature of resist sidewall at cross section A and a tapered cross section of sidewall at cross section B, respectively. Here, the sidewall feature can be gradually changed by gradually varying the numerical aperture (NA) of the second lens 307 between A and B.

As described above, according to the above examples, in order to form a desired pattern of latent image for microfluidic devices and the like in the resist film formed on the substrate, the resist film is directly exposed to the desired pattern using focused light beam in the ultraviolet region. This can eliminate photomasks as described in the conventional art. In addition, the diameter of the focused light beam can be controlled in response to the channel width of the major linear or curved pattern in a microfluidic device or the like. This enables to conveniently form a latent image of a desired pattern using the vector mode equivalent to single-path writing.

In addition, when the resist film is exposed to a linear or curved pattern in a mode equivalent to single-path writing, a pattern having a smoothly varied channel width can be easily formed by gradually varying the diameter of focused light beam on the resist surface. Furthermore, a pattern having a smooth profile (variation of channel depth) along the resist film thickness can be formed by gradually varying the amount of irradiation per unit area on the resist film along a line or curve. Moreover, a pattern having a smoothly varied profile (sidewall feature of the channel) along the cross section of the resist film in a linear or curved pattern can also be formed by gradually varying the numerical aperture (NA) of the objective lens in the optical system of focused light beam along a line or curve.

The patterning method disclosed in the embodiments of the invention can be used to form a channel pattern of a microfluidic device in a short period of time without any photomask that is expensive and that requires time to obtain. The channel pattern can be easily and rapidly modified or improved by simply editing data related to the desired channel pattern and control data on a computer. Furthermore, the present method can form a resist film pattern having a smoothly controlled depth and sidewall feature of the channel, which is infeasible in conventional exposure methods using photomasks.

As a result, the period of time for research and development and for trial production of microfluidic devices can be significantly reduced. Moreover, sophisticated and high-quality microfluidic devices having design parameters of three-dimensional features can be fabricated.

What is claimed is:

1. A patterning method of forming a desired latent image pattern by irradiating a resist film formed on a substrate with focused light beam, the method comprising:
adjusting intensity of the focused light beam or size thereof on the resist film depending on a design of the pattern to irradiate the resist film.

2. A patterning method according to claim 1, further comprising:
varying the diameter of the focused light beam on the resist film in a range of 5 μm to 500 μm.

3. A patterning method according to claim 1 or 2, wherein optical system including one or more lenses and a aperture is placed between a source of the focused light beam and the resist film, and the diameter of the focused light beam is adjusted by adjusting the aperture.

4. A patterning method according to any one of claims 1 to 3, wherein the amount of irradiation exposure density on the resist film is adjusted while the diameter of the focused light beam is adjusted.

5. A patterning method according to claim 4, wherein the amount of irradiation exposure density on the resist film is adjusted by controlling intensity of the focused light beam using an optical intensity modulation element provided in optical system placed between a source of the focused light beam and the resist film.

6. A patterning method according to claim 4 or 5, wherein the amount of irradiation exposure density on the resist film is adjusted by controlling a relative writing speed of the focused light beam on the resist surface.

7. A patterning method of forming a desired latent image pattern by irradiating a resist film formed on a substrate with focused light beam, the method comprising:
variably adjusting irradiation direction of the focused light beam or the position of the substrate depending on a design of the pattern while irradiating the resist film with the focused light beam.

8. A patterning method according to claim 7, further comprising:
adjusting sharpness of the focused light beam along the pattern.

9. A patterning method according to claim 7 or 8, wherein optical system including one or more lenses and a aperture is placed between a source of the focused light beam and the resist film, and the sharpness or depth of focus of the focused light beam is adjusted by adjusting the numerical aperture, NA, of an objective lens using the aperture.

10. A patterning method according to any one of claims 1 to 9, wherein a semiconductor light emitting device is used for a source of the focused light beam, the semiconductor light beam emitting device having an intensity distribution of emitted light beam primarily composed of wavelengths in the vicinity of 365 nm.
